(19) United States
(12) Patent Application Publication
(10) Pub. No.: US 2004/0000703 A1
(43) Pub. Date: Jan. 1, 2004

(54) Semiconductor package body having a lead frame with enhanced heat dissipation

(76) Inventors: Jui-chung Lee, Yunlin (TW); Chen-Jung Tsai, Hsinchu (TW); Chih-Wen Lin, Hsinchu (TW)

Correspondence Address: BIRCH STEWART KOLASCH & BIRCH, PO BOX 747, FALLS CHURCH, VA, 22040-0747, US

(21) Appl. No.: 10/327,893

(22) Filed: Dec. 26, 2002

(30) Foreign Application Priority Data
Jun. 27, 2002 (TW) 091114187

(51) Int. Cl. H01L 23/495; H01L 23/34

(52) U.S. Cl. 257/675; 257/666; 257/712; 257/676

(57) ABSTRACT

A semiconductor package body having a lead frame. The lead frame is electrically connected to a semiconductor chip via at least one bonding wire in the semiconductor package body. The lead frame has a die pedestal having a first surface and a second surface opposite each other, a base pad disposed outside the die pedestal, at least one connecting part providing a connection between the die pedestal and the base pad, and a plurality of leads. Each lead has an electrical connecting portion and a connecting foot portion, in which the electrical connecting portion is electrically connected to the semiconductor chip via the bonding wire, and the connecting foot portion is exposed to the exterior of the semiconductor package body, thereby providing enhanced heat dissipation.

### BACKGROUND OF THE INVENTION

1. Field of the Invention

The present invention relates to a lead frame device, more particularly, to a semiconductor package body having a lead frame with enhanced heat dissipation.

2. Description of the Related Art

As the amount of heat generated by a semiconductor chip increases with the increase in electronic components such as transistor, resistor, and capacitor contained thereon, effective dissipation of heat produced by semiconductor chips becomes a major concern among modern semiconductor package and system designers. To solve the problem, one approach embeds a heat sink within the semiconductor package. Also, in some cases, the heat sink is mounted in the semiconductor package in such a manner that a surface of the heat sink is exposed to the outside of the package body for more effective heat dissipation. However, the incorporation of a heat sink into a semiconductor package increases the production cost and assembly processes and requires extra equipment. Meanwhile, voids are subject to formation between the semiconductor chip and the heat sink, thereby promoting the formation of popcorn cracks in the package body during the high temperature curing process thereof.

For overcoming the problems arising from incorporation of heat sinks into semiconductor packages, U.S. Pat. No. 6,114,752 discloses a semiconductor package having a lead frame with a base pad exposed to the exterior of the package body. FIGS. 1A and 1B are sectional diagrams showing a conventional semiconductor package body. In the semiconductor package body, the lead frame comprises a plurality of leads 19 and die pads 14 in a first horizontal plane, and a plurality of base pads 17 in a second horizontal plane. Each of the leads 19 has an inner portion 20 and an outer portion 21, the die pads 14 form an opening 22, and the base pad 17 is connected to the die pad 14 by a pair of opposing coupling bars 18. Also, a semiconductor chip 13 is mounted on the die pads 14 with an adhesive 24, and electrically connected to the inner portion 20 of the lead 19 via bonding wires 12, allowing the chip 13 to be electrically accessible to external facilities via the outer portion 21 of the lead 19. Further, by transfer molding, the semiconductor package body is encapsulated by a resin encapsulant 11.

As shown in FIG. 1A, the base pad 17 is in the second horizontal plane underneath the first horizontal plane to face the bottom side 16 of the die pad 14, so that the base pad 17 is securely positioned underneath an opening 22 formed in the die pads 14. As shown in FIG. 1B, the base pad 17 is in the second horizontal plane up to the first horizontal plane to face the upper side 15 of the die pad 14.

The base pad 17 is exposed to the exterior of the package body to provide the chip 13 with a thermal conductive media to directly and efficiently dissipate the heat from the chip to the outside of the package body. This also eliminates the need for an internal heat sink to prevent popcorn cracks in the package body. However, since alignment of the chip 13 and the die pads 14 and the formation of the opening 22 between the die pads 14 are provided in the same step, it is very difficult to accurately control the coating position of the adhesive 24 and the placement of the die pads 14.

### SUMMARY OF THE INVENTION

The present invention discloses a semiconductor package body having a lead frame with enhanced heat dissipation to solve problems caused by prior art.

In the semiconductor package body, the lead frame is electrically connected to a semiconductor chip via at least one bonding wire in the semiconductor package body. The lead frame has a die pedestal having a first surface and a second surface opposite each other, a base pad disposed outside the die pedestal, at least one connecting part providing a connection between the die pedestal and the base pad, and a plurality of leads. Each lead has an electrical connecting portion and a connecting foot portion, in which the electrical connecting portion is electrically connected to the semiconductor chip via the bonding wire, and the connecting foot portion is exposed to the exterior of the semiconductor package body.

Accordingly, it is a principal object of the invention to provide the lead frame with the base pad exposed to the exterior of the package body to directly dissipate heat from the chip.

It is another object of the invention to use the base pad as a support of the die pedestal to prevent a shift of the die pedestal from molding process.

Yet another object of the invention is to provide a lead frame with enhanced heat dissipation without increasing process costs.

These and other objects of the present invention will become readily apparent upon further review of the following specification and drawings.

### BRIEF DESCRIPTION OF THE DRAWINGS

FIGS. 1A and 1B are sectional diagrams showing a conventional semiconductor package body.

FIG. 2A is a three-dimensional diagram showing a lead frame according to the first embodiment of the present invention.

FIG. 2B is a sectional diagram showing a first package body having the lead frame along line XX″ of FIG. 2A.

FIG. 2C is a sectional diagram showing a second package body having the lead frame along line XX″ of FIG. 2A.

FIG. 2D is a sectional diagram showing a third package body having the lead frame along line XX″ of FIG. 2A.

FIG. 3A is a three-dimensional diagram showing a lead frame according to the second embodiment of the present invention.

FIG. 3B is a sectional diagram showing a first package body having the lead frame along line XX″ of FIG. 3A.

FIG. 3C is a sectional diagram showing a second package body having the lead frame along line XX″ of FIG. 3A.

FIG. 3D is a sectional diagram showing a third package body having the lead frame along line XX″ of FIG. 3A.

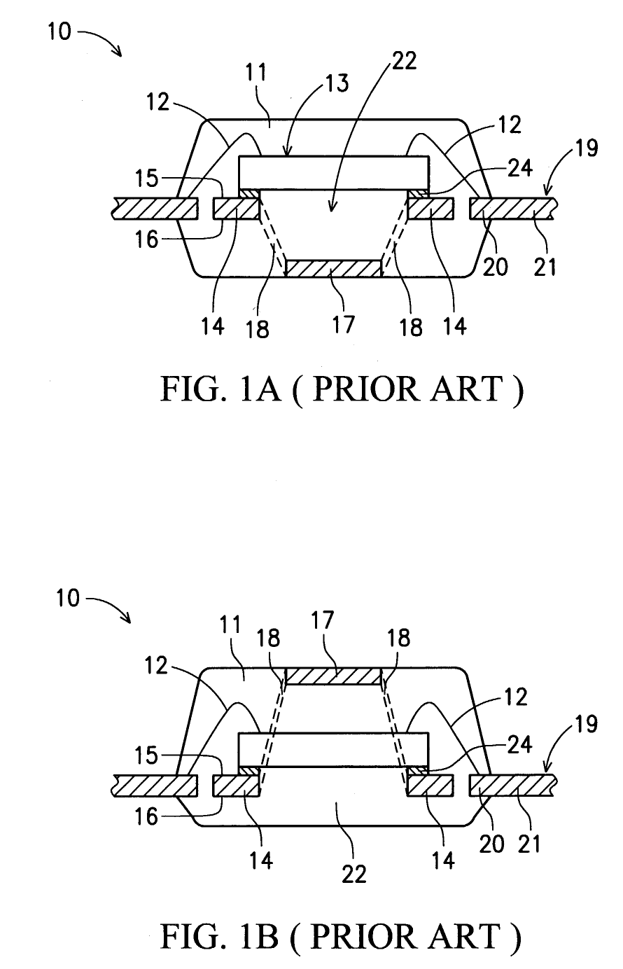

Similar reference characters denote corresponding features consistently throughout the attached drawings.

### DETAILED DESCRIPTION OF THE INVENTION

### First Embodiment

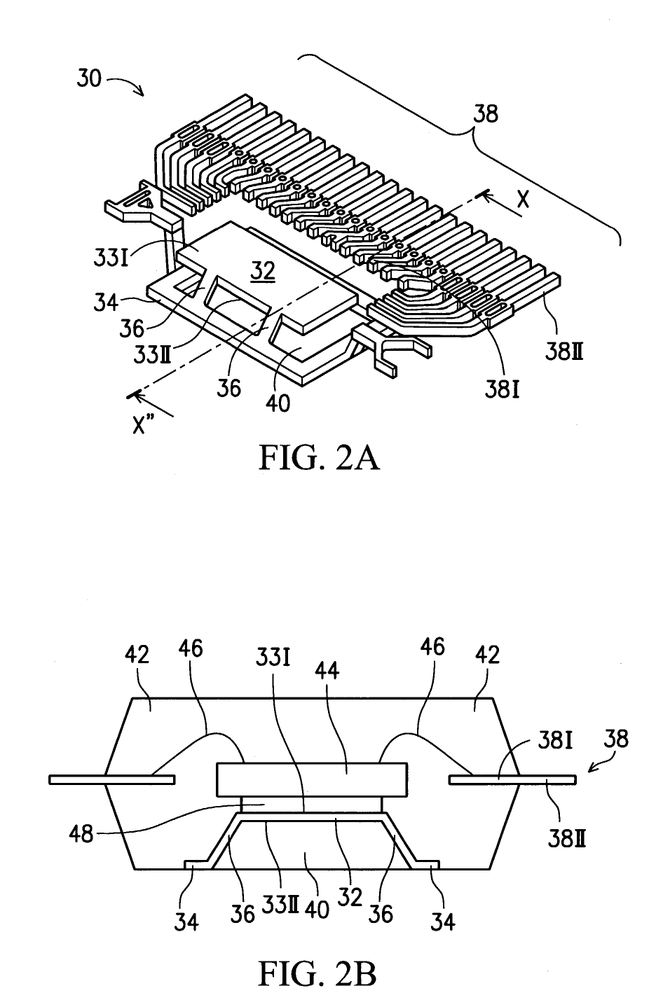

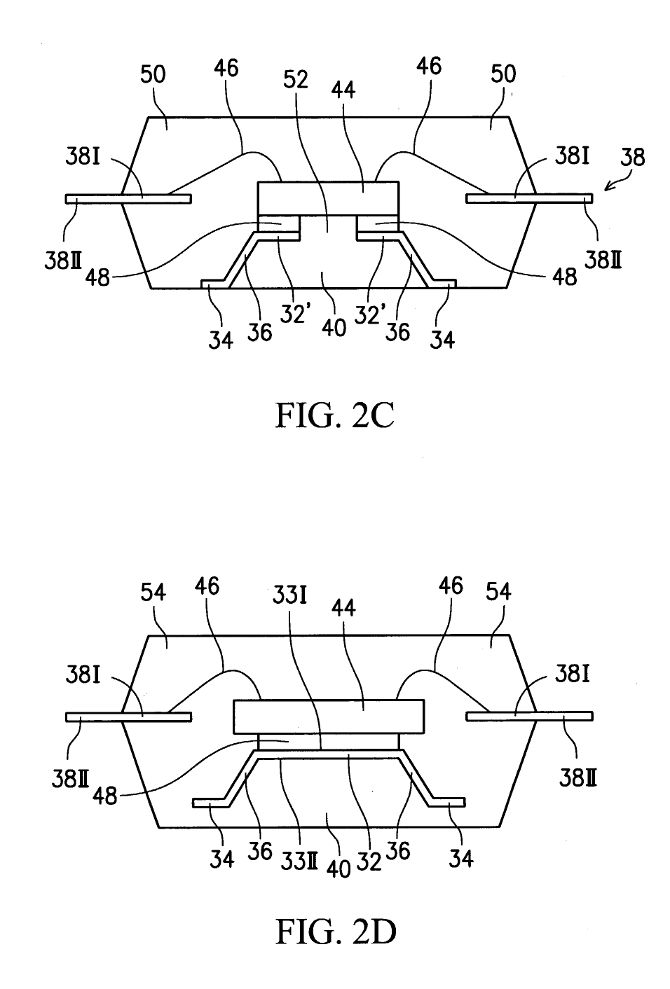

FIG. 2A is a three-dimensional diagram showing a lead frame according to the first embodiment of the present invention, in which a part of the leads in the symmetrical structure is not shown. A lead frame 30 comprises a die pedestal 32, a base pad 34, at least one connecting part 36 and a plurality of leads 38. The die pedestal 32 has a first surface 33I and a second surface 33II opposite each other. The connecting part 36 is employed to connect the die pedestal 32 and the base pad 34. The base pad 34 is in a ring shape to provide an opening 40, thus the projection of the die pedestal 32 is in the opening 40. The lead 38 has an electrical connecting portion 38I and a connecting foot portion 38II. In addition, the die pedestal 32, the connecting part 36, and the base pad 34 may all be formed in one structure.

FIG. 2B is a sectional diagram showing a first package body 42 having the lead frame 30 along line XX″ of FIG. 2A. The first package body 42 comprises the lead frame 30, and a semiconductor chip 44 electrically connected to the electrical connecting portion 38I of the lead 38 by bonding wires 46. For example, using ultrasonic welding, two ends of the bonding wire 46 ARE bonded on a bonding pad of the chip 44 and the electrical connecting portion 38I of the lead 38, respectively. The connecting foot portion 38II is not encapsulated and exposed to the exterior of the package body 42. The chip 44 is attached to the first surface 33I of the die pedestal 32 via an adhesion layer 48, such as silver-filled epoxy.

By transfer molding, the chip 44, the bonding wires 46 and a part of the lead frame 30 are encapsulated by a resin encapsulant, but part of the base pad 34 and the connecting foot portion 38II of the lead 38 are exposed. The exposed portion of the base pad 34 is leveled with the package body 42 to directly and efficiently dissipate the heat from the chip 44 outside the package body 42. Also, during the transfer molding, the base pad 34 is used as a support of the die pedestal 32 to prevent a shift of the die pedestal 32 from molding process. In addition, when the die pedestal 32 is smaller than the chip 44, the contact area between the chip 44 and the adhesive layer 48 is increased to prevent peeling in the interface between the chip 44 and the adhesive layer 48.

FIG. 2C is a sectional diagram showing a second package body 50 having the lead frame 30 along line XX″ of FIG. 2A. In the package body 50, the die pedestal 32′ of the lead frame 30 is in a ring shape to provide an opening 52. This can also increase the contact area between the chip 44 and the adhesive layer 48 to prevent peeling in the interface between the chip 44 and the adhesive layer 48.

FIG. 2D is a sectional diagram showing a third package body 54 having the lead frame 30 along line XX″ of FIG. 2A. By transfer molding the third package body 54, the chip 44, the bonding wires 46 and a part of the lead frame 30 are encapsulated by a resin encapsulant, resulting in exposure of only the connecting foot portion 38II of the lead 38. This encapsulates the base pad 34 to provide preferred mechanical protection. Also, the base pad 34 encapsulated into the package body 54 can serve as a heat sink to dissipate the heat from the chip 44.

### Second Embodiment

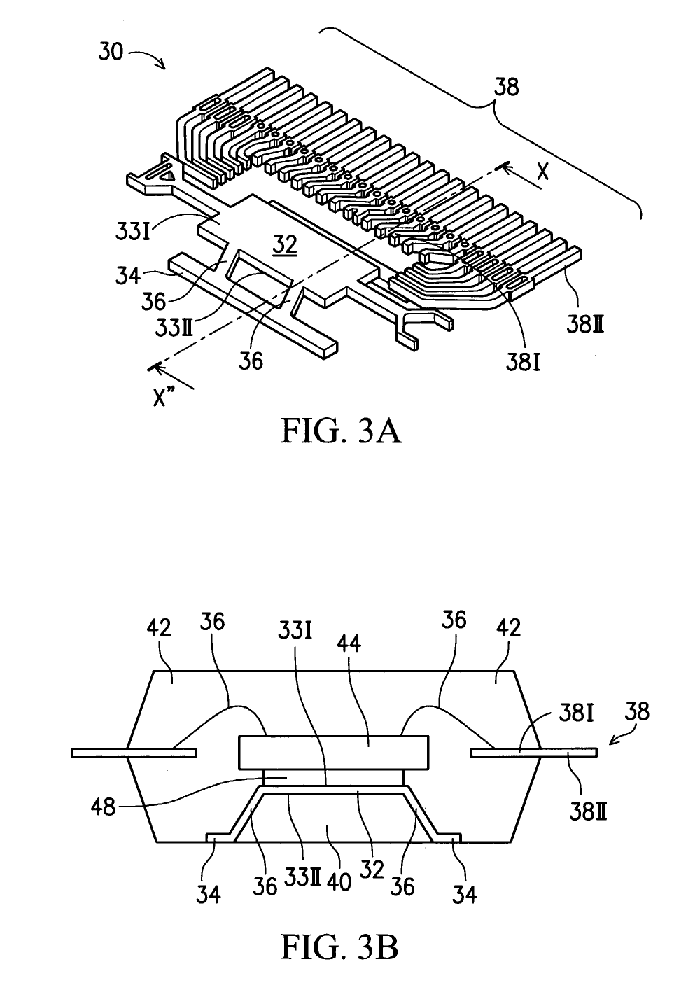

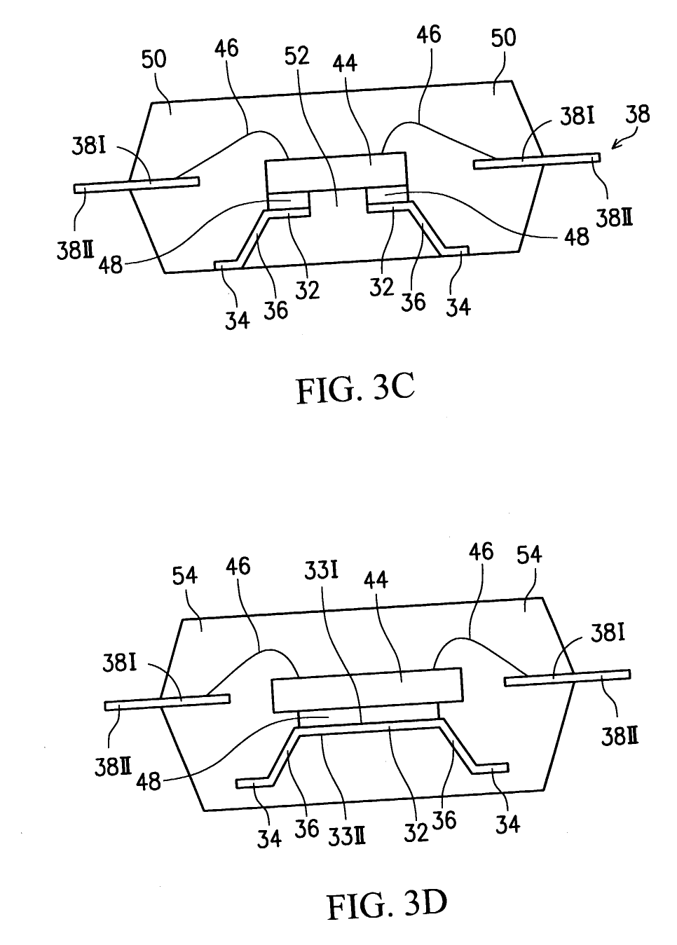

FIG. 3A is a three-dimensional diagram showing a lead frame according to the second embodiment of the present invention, in which a part of leads in the symmetrical structure is not shown. A lead frame 30 comprises a die pedestal 32, two base pads 34, at least one connecting part 36, and a plurality of leads 38. The die pedestal 32 has a first surface 33I and a second surface 33II opposite each other. The connecting part 36 is employed to connect the die pedestal 32 and the base pads 34. The projection of the die pedestal 32 is between the two strip-shaped base pads 34. The lead 38 has an electrical connecting portion 38I and a connecting foot portion 38II. The two base pads 34 may provide a two-strip profile or a quadrilateral profile. In addition, the die pedestal 32, the connecting part 36, and the base pad 34 may all be formed in one structure.

FIG. 3B is a sectional diagram showing a first package body 42 having the leadframe 30 along line XX″ of FIG. 3A. The first package body 42 comprises the lead frame 30, and a semiconductor chip 44 electrically connected to the electrical connecting portion 38I of the lead 38 by bonding wires 46. For example, using ultrasonic welding, two ends of the bonding wire 46 are bonded on a bonding pad of the chip 44 and the electrical connecting portion 38I of the lead 38, respectively. The connecting foot portion 38II is not encapsulated and exposed to the package body 42. The chip 44 is attached to the first surface 33I of the die pedestal 32 via an adhesion layer 48, such as silver-filled epoxy.

By transfer molding, the chip 44, the bonding wires 46 and a part of the lead frame 30 are encapsulated by a resin encapsulant, but part of the base pad 34 and the connecting foot portion 38II of the lead 38 are exposed. The exposed portion of the base pad 34 is leveled with the package body 42 to directly and efficiently dissipate the heat from the chip 44 to the outside of the package body 42. Also, during the transfer molding, the base pad 34 is used as a support of the die pedestal 32 to prevent a shift of the die pedestal 32 from molding process. In addition, when the die pedestal 32 is smaller than the chip 44, the contact area between the chip 44 and the adhesive layer 48 is increased to prevent peeling in the interface between the chip 44 and the adhesive layer 48.

FIG. 3C is a sectional diagram showing a second package body 50 having the lead frame 30 along line XX″ of FIG. 3A. In the package body 50, the die pedestal 32′ of the lead frame 30 is in a ring shape to provide an opening 52. This can also increase the contact area between the chip 44 and the adhesive layer 48 to prevent peeling in the interface between the chip 44 and the adhesive layer 48.

FIG. 3D is a sectional diagram showing a third package body 54 having the lead frame 30 along line XX″ of FIG. 3A. By transfer molding the third package body 54, the chip 44, the bonding wires 46, and a part of the lead frame 30 are encapsulated by a resin encapsulant, resulting in exposure of only the connecting foot portion 38II of the lead 38. This encapsulates the base pad 34 to provide preferred mechanical protection. Also, this encapsulates the base pad 34 into the package body 54 to serve as a heat sink to dissipate the heat from the chip 44.

It is to be understood that the present invention is not limited to the embodiments described above, but encompasses any and all embodiments within the scope of the following claims.

What is claimed is:

1. A semiconductor package body having a lead frame, the lead frame electrically connected to a semiconductor chip via at least one bonding wire in the semiconductor package body, the lead frame comprising:
a die pedestal encapsulated in the semiconductor package body and having a first surface and a second surface opposite each other, in which the semiconductor chip is disposed on the first surface of the die pedestal;
a base pad disposed outside the die pedestal;
at least one connecting part encapsulated in the semiconductor package body and providing a connection between the die pedestal and the base pad; and
a plurality of leads, wherein each lead has an electrical connecting portion and a connecting foot portion, the electrical connecting portion is electrically connected to the semiconductor chip via the bonding wire, and the connecting foot portion is exposed to the exterior of the semiconductor package body.

2. The semiconductor package body having a lead frame according to claim 1, wherein the base pad is in a ring shape to form an opening, and the projection of the die pedestal is in the opening.

3. The semiconductor package body having a lead frame according to claim 1, wherein a part of the base pad is exposed to the exterior of the semiconductor package body.

4. The semiconductor package body having a lead frame according to claim 3, wherein the exposed portion of the base pad is leveled with the semiconductor package body.

5. The semiconductor package body having a lead frame according to claim 1, wherein the die pedestal is in a ring shape to form an opening.

6. The semiconductor package body having a lead frame according to claim 1, wherein the die pedestal is smaller than the semiconductor chip.

7. The semiconductor package body having a lead frame according to claim 1, wherein the die pedestal is larger than the semiconductor chip.

8. The semiconductor package body having a lead frame according to claim 1, wherein the die pedestal, the base pad and the connecting part are all formed in one structure.

9. A semiconductor package body having a lead frame, the lead frame electrically connected to a semiconductor chip via at least one bonding wire in the semiconductor package body, the lead frame comprising:
a die pedestal encapsulated in the semiconductor package body and having a first surface and a second surface opposite each other, in which the semiconductor chip is disposed on the first surface of the die pedestal;
two base pads disposed outside the die pedestal;
at least one connecting part encapsulated in the semiconductor package body and providing a connection between the die pedestal and the base pads; and
a plurality of leads, wherein each lead has an electrical connecting portion and a connecting foot portion, the electrical connecting portion is electrically connected to the semiconductor chip via the bonding wire, and the connecting foot portion is exposed to the exterior of the semiconductor package body.

10. The semiconductor package body having a lead frame according to claim 9, wherein the two base pads provide a quadrilateral profile, and the projection of the die pedestal is in the opening.

11. The semiconductor package body having a lead frame according to claim 9, wherein a part of the base pad is exposed to the exterior of the semiconductor package body.

12. The semiconductor package body having a lead frame according to claim 11, wherein the exposed portion of the base pad is leveled with the semiconductor package body.

13. The semiconductor package body having a lead frame according to claim 9, wherein the base pad is in a ring shape to form an opening, and the projection of the die pedestal is in the opening.

14. The semiconductor package body having a lead frame according to claim 9, wherein the die pedestal is smaller than the semiconductor chip.

15. The semiconductor package body having a lead frame according to claim 9, wherein the die pedestal is larger than the semiconductor chip.

16. The semiconductor package body having a lead frame according to claim 8, wherein the die pedestal, the base pad, and the connecting part are all formed in one structure.
